(19) United States
(12) Patent Application Publication
(10) Pub. No.: US 2015/0366050 A1
(43) Pub. Date: Dec. 17, 2015

(54) SEMICONDUCTOR PACKAGE

(71) Applicant: SAMSUNG ELECTRONICS CO., LTD., Suwon-si (KR)

(72) Inventors: Bo-in Noh, Suwon-si (KR); Sang-won KIM, Asan-si (KR)

(73) Assignee: SAMSUNG ELECTRONICS CO., LTD., Suwon-si (KR)

(21) Appl. No.: 14/682,624

(22) Filed: Apr. 9, 2015

(30) Foreign Application Priority Data
Jun. 16, 2014 (KR) 10-2014-0072968

(51) Int. Cl. H05K 1/02; H05K 1/11; H05K 1/18; H05K 1/03

(52) U.S. Cl. CPC H05K 1/028; H05K 1/0346; H05K 1/111; H05K 1/181; H05K 2201/0311; H05K 2201/09381

(57) ABSTRACT

A semiconductor package includes: a first substrate; a second substrate disposed on the first substrate to be spaced apart from the first substrate, and including an active region on which semiconductor devices are configured to be mounted; and a flexible interconnection member electrically connecting the first substrate to the second substrate, the flexible interconnection member including a flexible film and a metal wiring member formed on the flexible film.

### CROSS-REFERENCE TO RELATED APPLICATION

This application claims priority to Korean Patent Application No. 10-2014-0072968, filed on Jun. 16, 2014, in the Korean Intellectual Property Office, the disclosure of which is incorporated herein in its entirety by reference.

### BACKGROUND

1. Field

The exemplary embodiments relate to semiconductor packages, and more particularly, to a semiconductor package that includes a plurality of semiconductor substrates on which semiconductor devices are mounted and a flexible interconnection member that connects the plurality of semiconductor substrates to each other.

2. Description of the Related Art

The current trend in the electronics industry is to develop compact, high-density, multi-functional, and high-speed electronic systems. In addition to research for obtaining compact and high-density electronic systems, research has been conducted into wearable/flexible semiconductor devices to develop portable and human-friendly products according to consumers' demands in the modern society. Flexible devices are flexible in contrast with existing hard and inflexible devices, and thus can be transformed into desired shapes. For example, flexible devices can be rolled, folded, or lengthened, and can perform a function. Due to the development of flexible devices, future products such as flexible displays capable of being carried in a folded or rolled state and flexible sensors that are attached to a human body to transmit several pieces of information about the human body, are expected to be realized. To this end, a wearable/flexible interconnection device needs to be developed.

### SUMMARY

The exemplary embodiments provide a semiconductor package that is rendered wearable and flexible by using a flexible connection member, the flexible connection member including a flexible film capable of being rolled or folded and a wiring member formed on the flexible film, as a connection terminal of a semiconductor device, and is made highly-integrated and compact.

According to an aspect of an exemplary embodiment, there is provided a semiconductor package including a first substrate; a second substrate disposed on the first substrate to be spaced apart from the first substrate, and including an active region configured to receive and mount semiconductor devices; and a flexible interconnection member electrically connecting the first substrate to the second substrate. The flexible interconnection member may include a flexible film and a metal wiring member formed on the flexible film.

According to an exemplary embodiment, the flexible film is polyimide.

According to an exemplary embodiment, the flexible interconnection member further includes a metallic adhesion member interposed between the metal wiring member and the flexible film.

According to an exemplary embodiment, the flexible interconnection member further includes a conductive pad formed on a surface of the first substrate and the active region of the second substrate, and the conductive pad contacts a side of the flexible film and a side of the metal wiring member.

According to an exemplary embodiment, the semiconductor package further includes a support member formed on an edge of an upper surface of the first substrate. The support member may support the upper surface of the first substrate and a lower surface of the second substrate such that the upper surface of the first substrate is spaced apart from the lower surface of the second substrate by a predetermined distance.

According to an exemplary embodiment, the metal wiring member extends in a first direction from the second substrate to the first substrate and a plurality of the metal wiring members are arranged parallel to each other in a second direction perpendicular to the first direction.

According to an exemplary embodiment, a plurality of the flexible interconnection members are provided, the plurality of flexible interconnection members each extend in a first direction from the second substrate to the first substrate and are arranged parallel to each other in a second direction perpendicular to the first direction, and a width of the flexible film in the second direction is substantially equal to a width of the metal wiring member in the second direction.

According to an exemplary embodiment, the first substrate is a printed circuit board including an active region, the second substrate is a semiconductor substrate including an active region and an inactive region formed opposite to the active region, and the flexible interconnection member electrically connects the active region of the first substrate to the active region of the second substrate.

According to an exemplary embodiment, a surface opposite to the active region of the first substrate faces the active region of the second substrate.

According to an exemplary embodiment, the active region of the first substrate faces the active region of the second substrate.

According to an aspect of another exemplary embodiment, there is provided a semiconductor package including a first substrate having a lower surface on which an active region is formed; a second substrate including a first surface on which an active region is formed and a second surface opposite to the first surface; an adhesion layer interposed between an upper surface of the first substrate and the second surface of the second substrate; and a flexible interconnection member that connects the lower surface of the first substrate to the first surface of the second substrate.

According to an exemplary embodiment, the flexible interconnection member includes a flexible film; a metal wiring member formed on an upper surface of the flexible film; and a metallic adhesion member interposed between the flexible film and the metal wiring member.

According to an exemplary embodiment, a size of a planar area of the first substrate is substantially equal to a size of a planar area of the second substrate.

According to an exemplary embodiment, the semiconductor package further includes a first conductive pad formed on edges of the lower surface of the first substrate and a second conductive pad formed on edges of the first surface of the second substrate. The first conductive pad is connected to a first end of the flexible interconnection member, and the second conductive pad is connected to a second end opposite to the first end of the flexible interconnection member.

According to an exemplary embodiment, the semiconductor package further includes an external connection pad formed on the lower surface of the first substrate and connected to an external device, wherein the external connection pad is surrounded by the flexible interconnection member.

### BRIEF DESCRIPTION OF THE DRAWINGS

Exemplary embodiments will be more clearly understood from the following detailed description taken in conjunction with the accompanying drawings in which:

FIG. 1 is a perspective view of a semiconductor package according to an exemplary embodiment;

FIG. 2 is a front view showing some components of the semiconductor device of FIG. 1;

FIG. 3 is a front view showing some major parts of the semiconductor device of FIG. 1;

FIG. 4 is a perspective view of a semiconductor package according to another exemplary embodiment;

FIG. 5 is a front view showing some major parts of the semiconductor device of FIG. 4;

FIG. 6 is a perspective view of a semiconductor package according to another exemplary embodiment;

FIG. 7 is a front view showing some components of the semiconductor device of FIG. 6;

FIGS. 8 and 9 are perspective views of semiconductor packages according to other exemplary embodiments;

FIG. 10 is a front view showing some major parts of the semiconductor device of FIG. 9;

FIGS. 11 and 12 are perspective views of semiconductor packages according to other exemplary embodiments;

FIG. 13 is a cross-sectional view of the semiconductor package of FIG. 12;

FIG. 14 is a plan view showing a major part of the semiconductor device of FIGS. 12 and 13;

FIG. 15 is a cross-sectional view of a semiconductor package according to another exemplary embodiment;

FIG. 16 is a cross-sectional view of a solid state drive (SSD) device to which a semiconductor package according to any of the exemplary embodiments may be applied; and

FIG. 17 is a perspective view of an electronic device to which a semiconductor package according to any of the exemplary embodiments may be applied.

### DETAILED DESCRIPTION OF THE EXEMPLARY EMBODIMENTS

As used herein, the term “and/or” includes any and all combinations of one or more of the associated listed items. Expressions such as “at least one of,” when preceding a list of elements, modify the entire list of elements and do not modify the individual elements of the list.

The exemplary embodiments will now be described more fully with reference to the accompanying drawings, in which exemplary embodiments are shown. The exemplary embodiments may, however, be embodied in many different forms and should not be construed as being limited to the exemplary embodiments set forth herein.

As such, variations from the shapes of the illustrations as a result, for example, of manufacturing techniques and/or tolerances, are to be expected. Thus, exemplary embodiments should not be construed as being limited to the particular shapes of regions illustrated herein but are to include deviations in shapes that result, for example, from manufacturing. Like numbers refer to like elements throughout the specification. Various elements and regions illustrated in the drawings are schematic in nature. Thus, the exemplary embodiments are not limited to relative sizes or intervals illustrated in the accompanying drawings. The terminology used herein is for the purpose of describing exemplary embodiments only and is not intended to be limiting of the exemplary embodiments.

As used herein, the term “and/or” includes any and all combinations of one or more of the associated listed items. Expressions such as “at least one of,” when preceding a list of elements, modify the entire list of elements and do not modify the individual elements of the list.

FIG. 1 is a schematic perspective view illustrating a three-dimensional (3D) structure of a semiconductor package 1000 according to an exemplary embodiment.

Referring to FIG. 1, the semiconductor package 1000 may include a first substrate 100, a second substrate 110 formed over the first substrate 100 to be spaced apart from the first substrate 100, a flexible interconnection member 200 electrically and/or physically connecting the first substrate 100 to the second substrate 110, and support members 300 formed on the edges of an upper surface of the first substrate 100.

The first substrate 100 may be formed in the shape of a rectangular plane extending in a first direction (e.g., an X direction) and a second direction (e.g., a Y direction). The first substrate 100 may be a flexible substrate capable of being bent or folded, such as a printed circuit board (PCB) or an epoxy glass or polyimide glass circuit board. According to an exemplary embodiment, the first substrate 100 may be a flexible PCB. An upper surface 100A of the first substrate 100 may be a main surface or active region on which semiconductor devices are formed.

The second substrate 110 may be spaced apart from the first substrate 100 by a predetermined distance in a third direction (e.g., a Z direction) and may be formed on the first substrate 100. The second substrate 110 may be formed of at least one selected from a silicon (Si) substrate, a germanium (Ge) substrate, an SiGe substrate, and a silicon-on-insulator (SOI) substrate. The second substrate 110 may include a semiconductor material, for example, a Group IV semiconductor, a Group III-V compound semiconductor, or a Group II-VI oxide semiconductor. According to an exemplary embodiment, the Group IV semiconductor may include Si, Ge, or SiGe. The second substrate 110 may be a bulky wafer or an epitaxial layer.

A first surface 110A of the second substrate 110 may include an active region on which semiconductor devices are mounted. The second substrate 110 may be disposed over the first substrate 100 such that the first surface 110A faces the upper surface 100A of the first substrate 100. The size of a planar area of the first substrate 100 may be greater than a size of the planar area of the second substrate 110.

The flexible interconnection member 200 may electrically and/or physically connect the upper surface 100A of the first substrate 100 to the first surface 110A of the second substrate 110. The flexible interconnection member 200 may be formed to connect a first edge side S1 of the first substrate 100 to an edge side S1′ opposite to the first edge side S1 from among edge sides of the first surface 110A of the second substrate 110. Similarly, the flexible interconnection member 200 may be formed to connect a second edge side S2 opposite to the first edge side S1 of the first substrate 100 to a side S2′ opposite to the second side S2 from among the edge sides of the first surface 110A of the second substrate 110. Although two flexible interconnection members 200 are illustrated in FIG. 1, the exemplary embodiments are not limited thereto, and one flexible interconnection member 200 or at least three flexible interconnection members 200 may be formed.

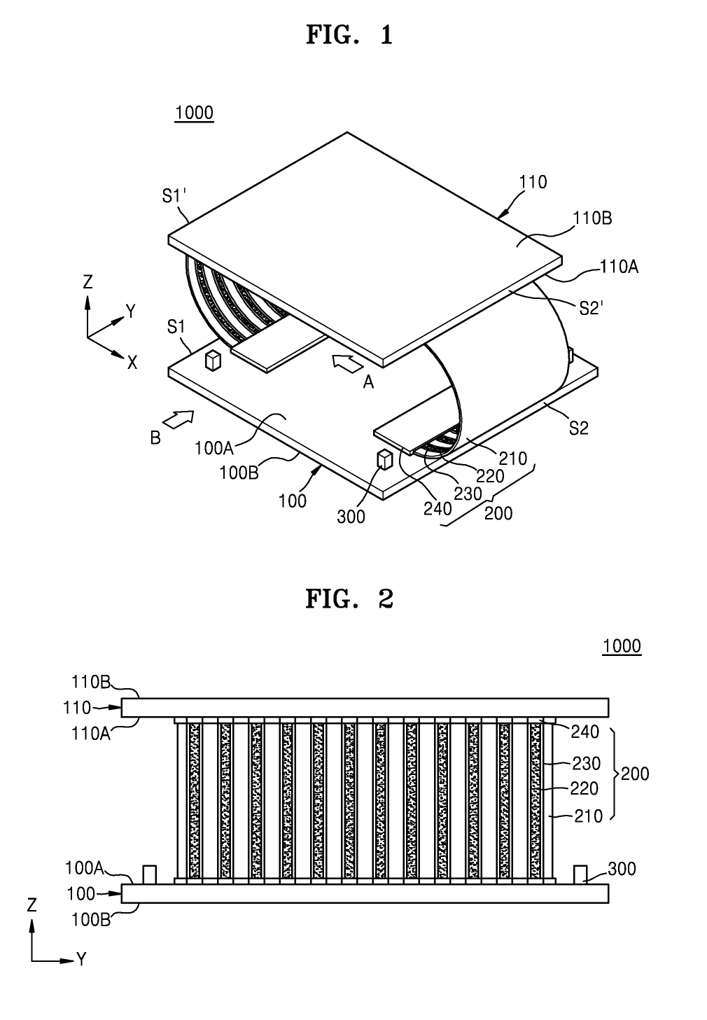

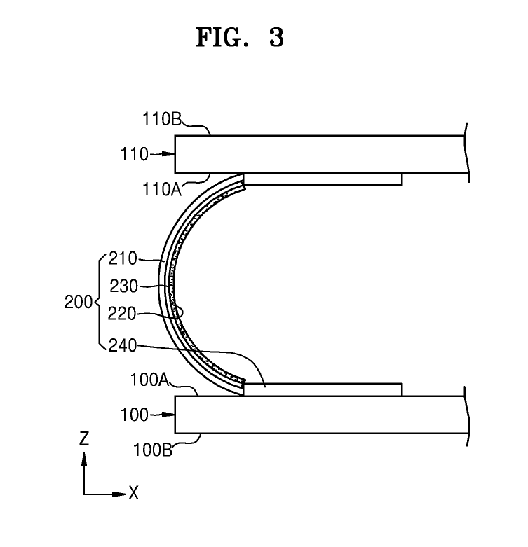

The flexible interconnection member 200 may be a flexible member capable of being bent or folded. The flexible interconnection member 200 may include a flexible film 210, wiring members 220 formed in the shape of thin films on the flexible film 210, metallic adhesion layers 230 interposed between the flexible film 210 and the wiring members 220, and conductive pads 240 connected to the flexible film 210 and the wiring members 220. A position relationship between the components of the flexible interconnection member 200 and the shapes of the components of the flexible interconnection member 200 will be described in more detail later with reference to FIGS. 2 and 3.

The conductive pads 240 may be formed in contact with the first edge side S1 of the first substrate 100, the second side S2 opposite to the first edge side S1 of the first substrate 100, and the edge sides S1′ and S2′ of the second substrate 110 respectively facing the first edge side S1 and the second edge side S2. The conductive pads 240 may extend in the second direction (e.g., the Y direction) and be parallel to the first edge side S1, the second edge side S2, and the edge sides S1′ and S2′ of the second substrate 110 respectively facing the first and second edge sides S1 and S2. The conductive pads 240 may be formed of at least one conductive material selected from a tin (Sn)-lead (Pb) alloy, copper (Cu) plated with nickel (Ni) or gold (Au), aluminum (Al), titanium (Ti), and graphite-based ink. According to an exemplary embodiment, the conductive pads 240 may be formed of Cu plated with an Sn—Pb alloy.

The support members 300 may be formed on the edges of the upper surface 100A of the first substrate 100. Although four support members 300 are formed on the upper surface 100A of the first substrate 100 in FIG. 1, the exemplary embodiments are not limited thereto. The support members 300 may be formed of the same material as a material used to form a PCB, such as plastic, injection molded plastic, or stamped metal. The support members 300 may serve to support the semiconductor package 1000 and prevent the second substrate 110 from resting on the first substrate 100 and contacting the first substrate 100 due to bending or folding of the flexible interconnection member 200. By adjusting the height of each of the support members 300, a minimal height of a connection portion of the flexible interconnection member 200 connecting the first substrate 100 to the second substrate 110 may be controlled.

The semiconductor package 1000 according to an exemplary embodiment uses the flexible interconnection members 200, which are capable of being bent or folded, as a connection unit between substrates on which semiconductor devices are mounted, and thus may be applied to wearable or flexible electronic products, which are popular these days. In addition, the height of the connection unit may vary due to the flexibility of the semiconductor package 1000, and thus compact, thin, and highly-integrated electronic products may be obtained. Furthermore, since the semiconductor package 1000 includes the flexible interconnection members 200, occurrence of errors due to degradation of the stress relaxation property of a semiconductor package and delamination thereof caused by an increase in rigidity of the semiconductor package when a connection unit thereof is formed of a Cu bump or a Cu pillar may be reduced.

FIG. 2 is a front view of a flexible interconnection member 200 of the semiconductor package 1000 viewed in a direction A.

Referring to FIG. 2, the flexible interconnection member 200 may electrically and/or physically connect the upper surface 100A of the first substrate 100, on which an active region is formed, to the first surface 110A of the second substrate 110, on which an active region is formed, and may extend in the third direction (e.g., the Z direction). The flexible interconnection member 200 may include a flexible film 210, a plurality of wiring members 220 formed on the flexible film 210, metallic adhesion layers 230 interposed between the flexible film 210 and the wiring members 220, and conductive pads 240 connecting the flexible film 210 and the wiring members 220 to the first substrate 100 and the second substrate 110.

The flexible film 210 may be bent or folded in the first direction (e.g., the X direction of FIG. 1) and may be formed of a flexible material that enables the height of the flexible film 210 to be adjusted in the third direction (e.g., the Z direction). The flexible film 210 may connect the first substrate 100 to the second substrate 110 and may extend in the second direction (e.g., the Y direction) and the third direction (e.g., the Z direction). The flexible film 210 may be formed of a flexible material, such as polyester or polyimide. According to an exemplary embodiment, the flexible film 210 may be formed of polyimide. The flexible film 210 may be formed to have a thickness of 10 μm to 500 μm.

The plurality of wiring members 220 may be formed on the flexible film 210. The plurality of wiring members 220 may be connected to the conductive pads 240 to extend in the third direction (e.g., the Z direction). The plurality of wiring members 220 may be arranged side by side in the second direction (e.g., the Y direction) and may each extend in the third direction (e.g., the Z direction). The plurality of wiring members 220 may be formed of a metal selected from Cu, Ni, gold (Au), Al, and Sn or an alloy thereof. According to an exemplary embodiment, the metal or the alloy may be formed on the metallic adhesion layers 230 formed on the upper surface of the flexible film 210 by electroplating to form thin films. The plurality of wiring members 220 may each be formed to have a thickness of 1 μm to 100 μm.

The metallic adhesion layers 230 may be interposed between the flexible film 210 and the plurality of wiring members 220. A width of each of the metallic adhesion layers 230 in the second direction (e.g., the Y direction) may be substantially the same as that of each of the plurality of wiring members 220 in the second direction (e.g., the Y direction). Similar to the plurality of wiring members 220, the metallic adhesion layers 230 may each extend in the third direction (e.g., the Z direction) between the conductive pads 240 respectively formed on the upper surface 100A of the first substrate 100 and the first surface 110A of the second substrate 110. The metallic adhesion layers 230 may improve adhesion between the flexible film 210 and the plurality of wiring members 220. The metallic adhesion layers 230 may be formed of at least one selected from chromium (Cr), Ni, and a Cr—Ni alloy. The metallic adhesion layers 230 may be formed by depositing the aforementioned material on the flexible film 210 by sputtering. The metallic adhesion layers 230 may be formed to be thinner than the flexible film 210 and the plurality of wiring members 220, although are not limited thereto. According to an exemplary embodiment, the metallic adhesion layers 230 may each have a thickness of 100 Å to 5000 Å.

FIG. 3 is a front view of the first substrate 100, the second substrate 110, and the flexible interconnection member 200 of the semiconductor package 1000 viewed in a direction B of FIG. 1.

Referring to FIG. 3, the conductive pads 240 may be respectively formed on the upper surface 100A of the first substrate 100 and the first surface 110A of the second substrate 110, and the flexible film 210, the wiring members 220, and the metallic adhesion layers 230 may be connected to the conductive pads 240. The flexible interconnection member 200 may include the flexible film 210, the metallic adhesion layers 230 formed in the shape of thin films on the flexible film 210, the wiring members 220 formed on the metallic adhesion layers 230, and the conductive pads 240. The flexible film 210, the metallic adhesion layers 230, and the plurality of wiring members 220 may be sequentially stacked. As described above with reference to FIGS. 1 and 2, since the flexible film 210 is formed of a flexible material configured to be bent or folded, the flexible film 210 may be formed to be bent in the first direction (e.g., the X direction). The wiring members 220 and the metallic adhesion layers 230 may also be formed to be bent in the first direction (e.g., the X direction), similar to the flexible film 210.

FIG. 4 is a schematic perspective view illustrating a 3D structure of a semiconductor package 1100 according to another exemplary embodiment.

Referring to FIG. 4, although the semiconductor package 1100 may have the same components as those of the semiconductor package 1000 of FIG. 1, the semiconductor package 1100 is different from the semiconductor package 1000 in that a second surface 110B of the second substrate 110 of the semiconductor package 1100 faces the upper surface 100A of the first substrate 100. A first substrate 100, a second substrate 110, flexible interconnection members 200, and support members 300 included in the semiconductor package 1100 are the same as those described above with reference to FIG. 1, and a repeated description thereof will be omitted.

A first surface 110A of the second substrate 110 may include an active region on which semiconductor devices are mounted, and the second surface 110B opposite to the first surface 110A may include an inactive region formed thereon. Conductive pads 240 may be formed on the first surface 110A of the second substrate 110 and on the upper surface 100A of the first substrate 100.

Since the semiconductor package 1100 includes the flexible interconnection members 200, since the conductive pads 240 are formed on the first surface 110A of the second substrate 110, and since the second surface 110B of the second substrate 110 faces the upper surface 100A of the first substrate 100, when the first substrate 100 is a flexible PCB and accordingly is bent or folded in the third direction (e.g., the Z direction), the flexible interconnection members 200 may support the second substrate 110, thereby securing flexibility.

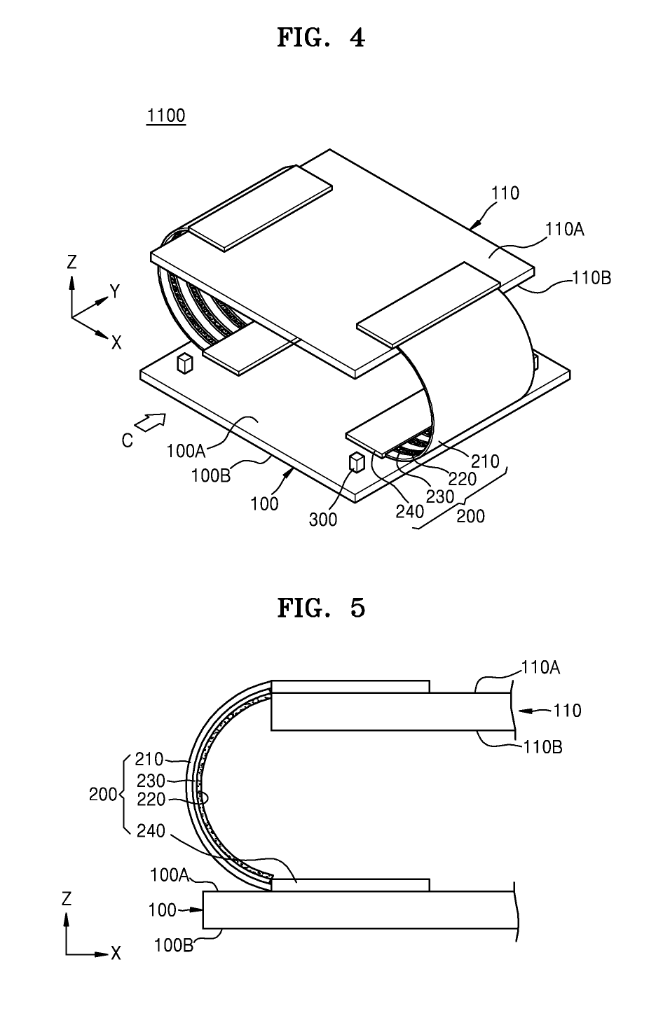

FIG. 5 is a front view of the semiconductor package 1100 of FIG. 4 viewed in a direction C.

Referring to FIG. 5, the conductive pads 240 may be formed on the upper surface 100A of the first substrate 100, on which an active region is formed, and the first surface 110A of the second substrate 110, on which an active region is formed, and the flexible film 210, the wiring members 220, and the metallic adhesion layers 230 may be connected to the conductive pads 240. The flexible interconnection member 200 may include the flexible film 210, the metallic adhesion layers 230 formed in the shape of thin films on the flexible film 210, the wiring members 220 formed on the metallic adhesion layers 230, and the conductive pads 240. Since the flexible interconnection member 200 is the same as those described above with reference to FIGS. 2 and 3, a repeated description thereof will be omitted.

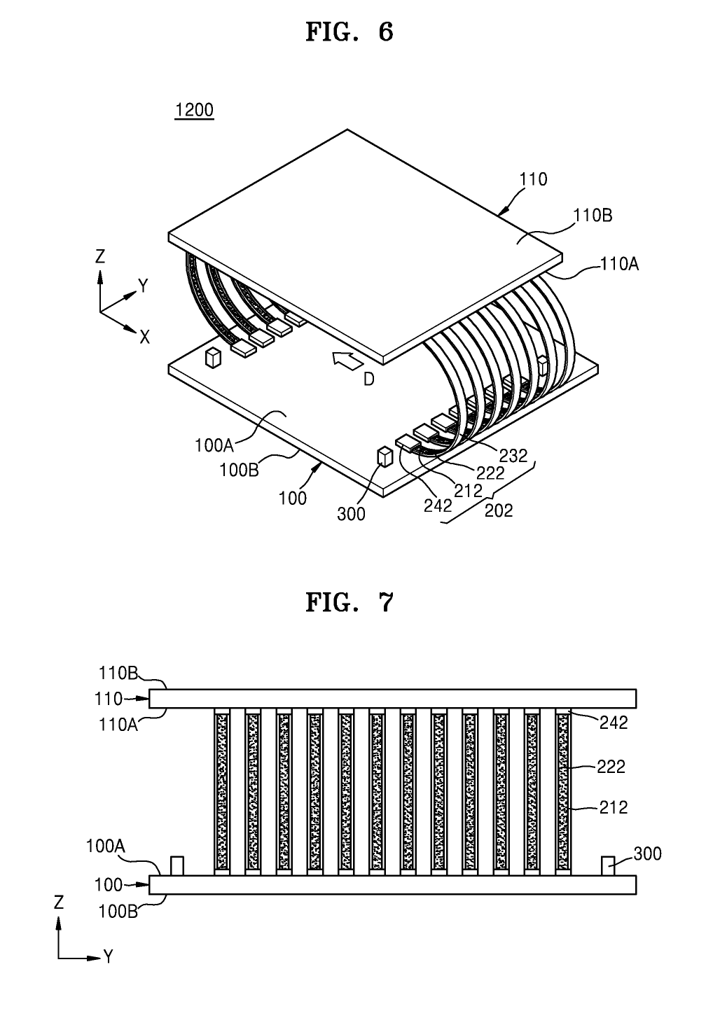

FIG. 6 is a schematic perspective view illustrating a 3D structure of a semiconductor package 1200 according to another exemplary embodiment. FIG. 7 is a front view of the semiconductor package 1200 of FIG. 6 viewed in a direction D.

Referring to FIGS. 6 and 7, the semiconductor package 1200 may include a first substrate 100, a second substrate 110 formed over the first substrate 100 to be spaced apart from the first substrate 100, a plurality of flexible interconnection members 202 electrically and/or physically connecting the first substrate 100 to the second substrate 110, and support members 300 formed on edges of an upper surface of the first substrate 100. The semiconductor package 1200 is different from the semiconductor package 1000 of FIG. 1 in that the plurality of flexible interconnection members 202 are formed. Since the first substrate 100, the second substrate 110, and the support members 300 are the same as those described above with reference to FIG. 1, a repeated description thereof will be omitted.

The plurality of flexible interconnection members 202 may include a plurality of flexible films 212, a plurality of wiring members 222, a plurality of metallic adhesion layers 232, and a plurality of conductive pads 242. The plurality of flexible interconnection members 202 may each be bent in the first direction (e.g., the X direction), connect the first substrate 100 to the second substrate 110, and extend in the third direction (e.g., the Z direction).

The plurality of flexible films 212 may connect the first substrate 100 to the second substrate 110 and may each extend in the third direction (e.g., the Z direction). The plurality of flexible films 212 may be arranged in parallel to each other in the second direction (e.g., the Y direction). The plurality of flexible films 212 may each be formed to have a thickness of 10 μm to 500 μm. Since a material used to form the plurality of flexible films 212 and a method of forming the same are the same as those for the flexible film 210 of FIGS. 1 and 2, a repeated description thereof will be omitted.

The plurality of wiring members 222 may be formed on the plurality of flexible films 212. The plurality of wiring members 222 may extend in the third direction (e.g., the Z direction), which is a lengthwise direction of the wiring members 222, along the plurality of flexible films 212, and may be arranged in parallel to each other in the second direction (e.g., the Y direction). A width of each of the plurality of wiring members 222 in the second direction (e.g., the Y direction) may be less than or substantially equal to a width of each of the plurality of flexible films 212 in the second direction (e.g., the Y direction). The plurality of wiring members 220 may each be formed to have a thickness of 1 μm to 100 μm. Since a material used to form the plurality of wiring members 222 and a method of forming the plurality of wiring members 222 may be the same as those for the plurality of wiring members 220 of FIGS. 1 and 2, a repeated description thereof will be omitted.

The plurality of metallic adhesion layers 232 may be interposed between the plurality of flexible films 212 and the plurality of wiring members 222. The plurality of metal adhesion layers 232 may extend on the plurality of flexible films 212 in the third direction (e.g., the Z direction) along the plurality of flexible films 212, and may be arranged in parallel to each other in the second direction (e.g., the Y direction). The plurality of metallic adhesion layers 232 may each be formed to have a width that is less than a width of each of the flexible films 212 in the second direction (e.g., the Y direction) and substantially equal to a width of each of the plurality of wiring members 222 in the second direction (e.g., the Y direction). Each of the plurality of metallic adhesion layers 232 may be formed to have a thickness of 100 Å to 5000 Å. Since a material used to form the plurality of metallic adhesion layers 232 and a method of forming the plurality of metallic adhesion layers 232 may be the same as those for the metallic adhesion layers 230 of FIGS. 1 and 2, a repeated description thereof will be omitted.

A stack of the plurality of flexible films 212, the plurality of wiring members 222, and the plurality of metallic adhesion layers 232 may be the same as the cross-section of the flexible interconnection member 200 of FIG. 3, and thus a repeated description thereof will be omitted.

The plurality of conductive pads 242 may be formed on an edge side of the upper surface 100A of the first substrate 110 and an opposite edge side of the upper surface 100A and on an edge side of the first surface 110A of the second substrate 110 and an opposite edge side of the first surface 110A. The plurality of conductive pads 242 may be arranged in parallel to each other in the second direction (e.g., the Y direction) on the upper surface 100A of the first substrate 100 and the first surface 110A of the second substrate 110. The plurality of conductive pads 242 may be electrically and/or physically connected to the plurality of flexible films 212, the plurality of wiring members 222, and the plurality of metallic adhesion layers 232.

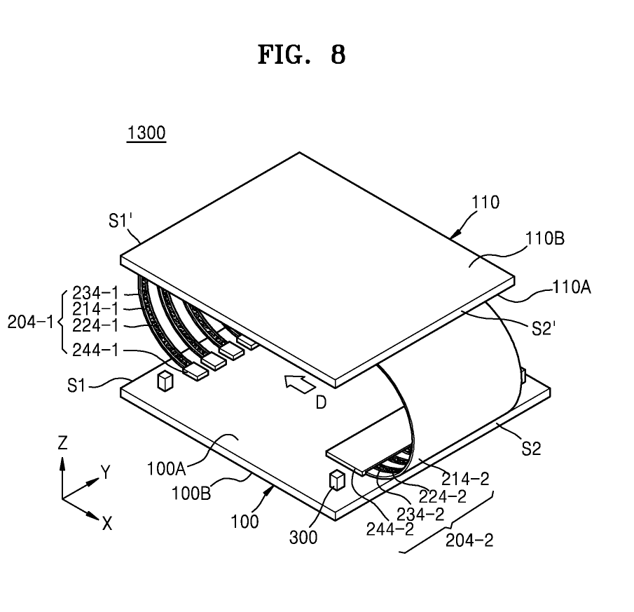

FIG. 8 is a schematic perspective view illustrating a 3D structure of a semiconductor package 1300 according to an exemplary embodiment.

Referring to FIG. 8, the semiconductor package 1300 may include a first substrate 100, a second substrate 110 formed over the first substrate 100 to be spaced apart from the first substrate 100, a first flexible interconnection member 204-1 and a plurality of second flexible interconnection members 204-2 electrically and/or physically connecting the first substrate 100 to the second substrate 110, and support members 300 formed on the edges of an upper surface of the first substrate 100. The semiconductor package 1300 is different from the semiconductor package 1000 of FIG. 1 in that the semiconductor package 1300 includes the first flexible interconnection member 204-1 and the plurality of second flexible interconnection members 204-2 that are respectively formed between edge sides of the first substrate 100 and the second substrate 110 facing each other and have different shapes. Since the first substrate 100, the second substrate 110, and the support members 300 are the same as those described above with reference to FIG. 1, a repeated description thereof will be omitted.

The first flexible interconnection member 204-1 and the second flexible interconnection members 204-2 electrically and/or physically connecting the upper surface 100A of the first substrate 100 to the first surface 110A of the second substrate 110 may each extend in the third direction (e.g., the Z direction). The first flexible interconnection member 204-1 may be formed to connect a first edge side S1 of the first substrate 100 to an edge side S1′ that is opposite to the first edge side S1 and is on the first surface 110A of the second substrate 110. The plurality of second flexible interconnection members 204-2 may be formed to connect a second edge side S2 of the first substrate 100 to an edge side S2′ that is opposite to the second edge side S2 and is on the first surface 110A of the second substrate 110. Thus, a flexible interconnection member formed between a first edge side of the upper surface 100A of the first substrate 100 and a first edge side of the first surface 110A of the second substrate 110 facing each other may be different, in terms of type and shape, from a flexible interconnection member formed between a second edge side of the upper surface 100A of the first substrate 100 and a second edge side of the first surface 110A of the second substrate 110 that are opposite to the respective first edge sides and face the respective first edge sides.

The first flexible interconnection member 204-1 may include a first flexible film 214-1 extending in the second direction (e.g., the Y direction) perpendicular to the third direction (e.g., the Z direction), which is a lengthwise direction of the first flexible interconnection member 204-1, a plurality of first wiring members 224-1 formed on the first flexible film 214-1 and arranged in parallel to each other in the second direction (e.g., the Y direction), a plurality of first metallic adhesion layers 234-1 interposed between the first flexible film 214-1 and the plurality of first wiring members 224-1 and having a width in the second direction (e.g., the Y direction) that is substantially equal to that of each of the plurality of first wiring members 224-1 in the second direction (e.g., the Y direction), and first conductive pads 244-1 connected to the first flexible film 214-1, the plurality of first wiring members 224-1, and the plurality of first metallic adhesion layers 234-1 and formed on the upper surface 100A of the first substrate 100 and the first surface 110A of the second substrate 110. Since the first flexible film 214-1, the plurality of first wiring members 224-1, the plurality of first metallic adhesion layers 234-1, and the first conductive pads 244-1 may be respectively the same as the flexible film 210, the wiring members 220, the metallic adhesion layers 230, and the conductive pads 240 illustrated in FIGS. 1-3, a repeated description thereof will be omitted.

The plurality of second flexible interconnection members 204-2 may each extend in the third direction (e.g., the Z direction), which is a lengthwise direction of the second flexible interconnection members 204-2. The plurality of second flexible interconnection members 204-2 may be arranged in parallel to each other in the second direction (e.g., the Y direction). The plurality of second flexible interconnection members 204-2 may include a plurality of second flexible films 214-2, a plurality of second wiring members 224-2 formed on the plurality of second flexible films 214-2, a plurality of metallic adhesion layers 234-2 interposed between the plurality of second flexible films 214-2 and the plurality of wiring members 224-2, and a plurality of second conductive pads 244-2 connected to the plurality of second flexible films 214-2, the plurality of wiring members 224-2, and the plurality of metallic adhesion layers 234-2 and contacting the upper surface 100A of the first substrate 100 and the first surface 110A of the second substrate 110. A width of each of the plurality of second wiring members 224-2 in the second direction (e.g., the Y direction) may be less than or substantially equal to that of each of the plurality of second flexible films 214-2 in the second direction (e.g., the Y direction). A width of each of the plurality of second metallic adhesion layers 234-2 in the second direction (e.g., the Y direction) may be substantially equal to that of each of the plurality of second wiring members 224-2 in the second direction (e.g., the Y direction). Since the plurality of second flexible films 214-2, the plurality of second wiring members 224-2, the plurality of second metallic adhesion layers 234-2, and the plurality of second conductive pads 244-2 may be respectively the same as the plurality of flexible films 212, the plurality of wiring members 222, the plurality of metallic adhesion layers 232, and the plurality of conductive pads 242 illustrated in FIGS. 6 and 7, a repeated description thereof will be omitted.

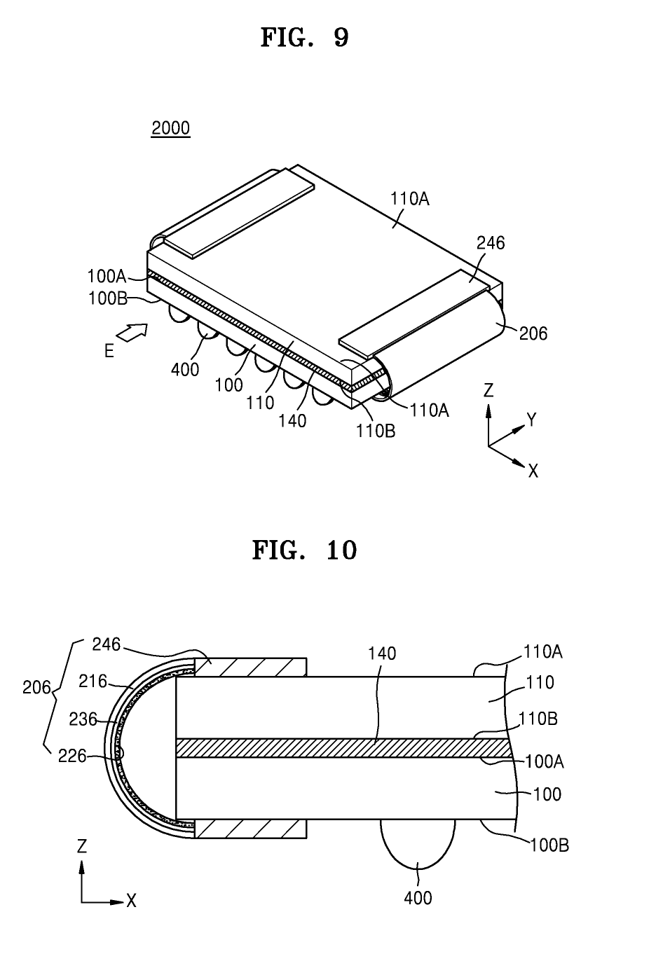

FIG. 9 is a perspective view illustrating a 3D structure of a semiconductor package 2000 according to another exemplary embodiment. FIG. 10 is a front view of major elements of the semiconductor package 2000 viewed in a direction E of FIG. 9.

Referring to FIG. 9, the semiconductor package 2000 may include a first substrate 100, a second substrate 110 formed on the first substrate 100, an adhesion layer 140 interposed between the first substrate 100 and the second substrate 110, a flexible interconnection member 206 connecting the first substrate 100 to the second substrate 110, and an external connection member 400 formed on a lower surface 100B of the first substrate 100 and connected to an external device.

The first substrate 100 may be formed in the shape of a rectangular plane extending in the first direction (e.g., the X direction) and the second direction (e.g., the Y direction). The first substrate 100 may be a flexible substrate capable of being bent or folded, like a PCB or an epoxy glass or polyimide glass circuit board. The lower surface 100B of the first substrate 100 may include an active region on which semiconductor devices are formed. Since a material used to form the first substrate 100 and properties of the first substrate 100 are the same as those for the first substrate 100 described above with reference to FIG. 1, a repeated description thereof will be omitted.

The second substrate 110 may be formed on the first substrate 100 and have a planar area substantially equal to a planar area of the first substrate 100. A first surface 110A of the second substrate 110 may include an active region formed thereon. A second surface 110B opposite to the first surface 110A may include an inactive region. Since a material used to form the second substrate 110 and properties of the second substrate 110 are the same as those for the second substrate 100 described above with reference to FIG. 1, a repeated description thereof will be omitted.

The adhesion layer 140 may be interposed between the first substrate 100 and the second substrate 110. In detail, the adhesion layer 140 may contact the upper surface 100A of the first substrate 100 and the second surface 110B of the second substrate 110. The size of a planar area of the adhesion layer 140 may be substantially equal to a size of a planar area of each of the first and second substrates 100 and 110. The adhesion layer 140 may be formed of at least one selected from, for example, epoxy resin, an NCF, a UV film, an instant adhesive, a thermosetting adhesive, a laser hardening adhesive, an ultrasonic hardening adhesive, and an NCP. The adhesion layer 140 may attach and fix the second surface 110B of the second substrate 110 to the upper surface 100A of the first substrate 100.

The external support member 400 may be formed on the lower surface 100B of the first substrate 100. The external connection member 400 may mount the semiconductor package 2000 on an external system board or a main board. The external connection member 400 may be formed of at least one selected from conductive materials such as Cu, Al, silver (Ag), Sn, Au, and solder. However, the material used to form the external connection member 400 is not limited thereto. The external connection member 400 may be formed as a single layer or as multiple layers. The external connection member 400 may be formed on the center of the lower surface 100B of the first substrate 100 so as to be surrounded by the conductive pad 246 (see FIG. 10).

The flexible interconnection member 206 may electrically and/or physically connect the upper surface 100B of the first substrate 100, which includes an active region, to the first surface 110A of the second substrate 110, which includes an active region. The flexible interconnection member 206 may be formed between an edge of the lower surface 100B of the first substrate 100 and an edge of the first surface 110A of the second substrate 110 that faces the edge of the lower surface 100B. Although two flexible interconnection members 206 are illustrated in FIG. 9, the exemplary embodiments are not limited thereto, and one flexible interconnection member 206 or at least three flexible interconnection members 206 may be formed.

Referring to FIG. 10, the flexible interconnection member 206 may be a flexible member capable of being bent or folded. The flexible interconnection member 206 may include a flexible film 216, wiring members 226 formed in the shape of thin films on the flexible film 216, metallic adhesion layers 236 interposed between the flexible film 216 and the wiring members 226, and conductive pads 246 connected to the flexible film 216 and the wiring members 226. A position relationship between the components of the flexible interconnection member 206 and the shapes of the components of the flexible interconnection member 206 may be the same as those for the flexible interconnection member 200 described above with reference to FIGS. 2 and 3, and thus a repeated description thereof will be omitted.

In the semiconductor package 2000 according to an exemplary embodiment, the lower surface 100B of the first substrate 100 is connected to the first surface 110A of the second substrate 110 by the flexible interconnection member 206, and the upper surface 100A of the first substrate 100 including an inactive region is attached and fixed to the second surface 110B of the second substrate 110 by the adhesion layer 140. Thus, the semiconductor package 2000 may be made more compact than when using a general conductive connection member such as a solder bump, leading to improved integration of a semiconductor device into other devices.

FIG. 11 is a perspective view illustrating a 3D structure of a semiconductor package 2100 according to another exemplary embodiment.

Referring to FIG. 11, the semiconductor package 2100 may include a first substrate 100, a second substrate 110 formed on the first substrate 100, an adhesion layer 140 interposed between the first substrate 100 and the second substrate 110, a flexible interconnection member 208 connecting the first substrate 100 to the second substrate 110, and an external connection member 400 formed on a lower surface 100B of the first substrate 100 and connected to an external device. The semiconductor package 2100 is different from the semiconductor package 2000 of FIGS. 9 and 10 in that a plurality of flexible interconnection members 208 are formed. Since the first substrate 100, the second substrate 110, the adhesion layer 140, and the external connection member 440 may be the same as those described above with reference to FIGS. 9 and 10, a repeated description thereof will be omitted.

The plurality of flexible interconnection members 208 may include a plurality of flexible films 218, a plurality of wiring members 228, and a plurality of conductive pads 248. The plurality of flexible interconnection members 208 may each be bent in the first direction (e.g., the X direction), connect the first substrate 100 to the second substrate 110, and each extend in the third direction (e.g., the Z direction).

The plurality of flexible films 218 may connect the first substrate 100 to the second substrate 110 and may each extend in the third direction (e.g., the Z direction), which is a lengthwise direction of the flexible films 218. The plurality of flexible films 218 may be arranged in parallel to each other in the second direction (e.g., the Y direction). The plurality of wiring members 228 may be formed on the plurality of flexible films 218. The plurality of wiring members 228 may extend in the third direction (e.g., the Z direction), which is a lengthwise direction of the wiring members 228, along the plurality of flexible films 218, and may be arranged in parallel to each other in the second direction (e.g., the Y direction). A width of each of the plurality of wiring members 222 in the second direction (e.g., the Y direction) may be less than or substantially equal to that of each of the plurality of flexible films 218 in the second direction (e.g., the Y direction). The plurality of conductive pads 248 may be formed on an edge side of the lower surface 100B of the first substrate 110 and an opposite side to the edge side of the lower surface 100B, and on an edge side of the first surface 110A of the second substrate 110 and an opposite side to the edge side of the first surface 110A. The plurality of conductive pads 248 may be arranged in parallel to each other in the second direction (e.g., the Y direction) on the lower surface 100B of the first substrate 100 and the first surface 110A of the second substrate 110. The plurality of flexible films 218, the plurality of wiring members 228, and the plurality of conductive pads 242 may be formed in the same shapes, of the same material, and using the same method as those for the plurality of flexible films 212, the plurality of wiring members 222, and the plurality of conductive pads 242 illustrated in FIG. 6, respectively, and thus a repeated description of these features described above with reference to FIG. 6 will be omitted. According to an exemplary embodiment, a plurality of metallic adhesion layers may be interposed between the plurality of flexible films 218 and the plurality of wiring members 228.

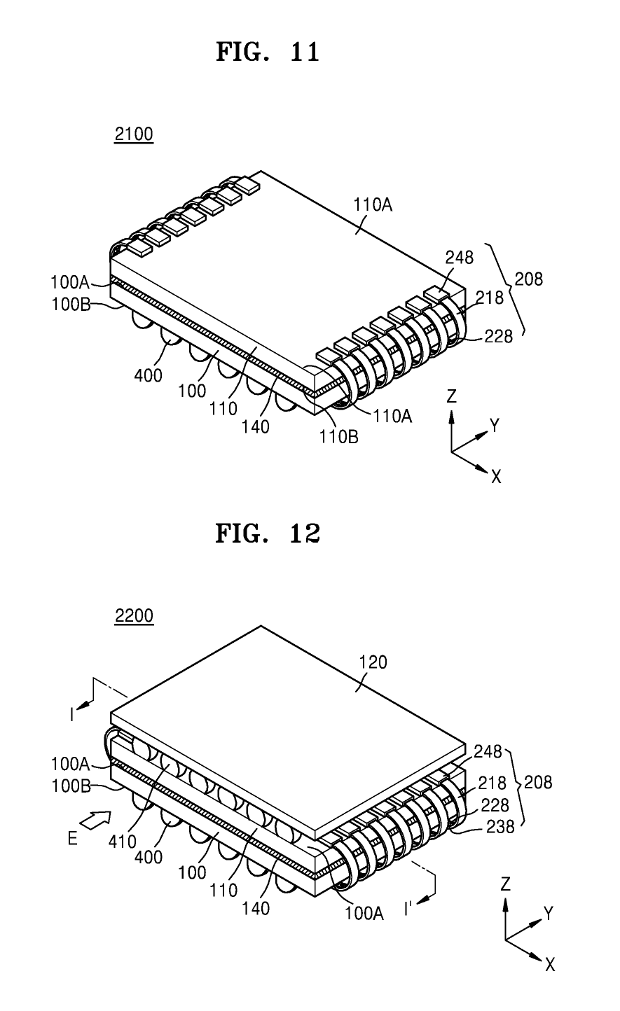

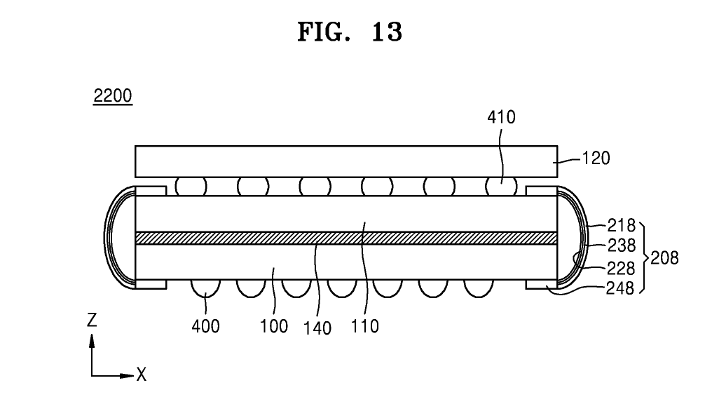

FIG. 12 is a perspective view illustrating a 3D structure of a semiconductor package 2200 according to another exemplary embodiment. FIG. 13 is a front view of major elements of the semiconductor package 2200 viewed in a direction E of FIG. 12.

Referring to FIGS. 12 and 13, the semiconductor package 2200 includes the same components as those of the semiconductor package 2100 of FIG. 11, and may further include a third substrate 120 formed on the second substrate 110 and an inter-substrate connection member 410 interposed between the second substrate 110 and the third substrate 120. Descriptions of components of the semiconductor package 2200 which are the same as components of the semiconductor package 2100 of FIG. 11 have already been described in reference to FIG. 11, and repeated descriptions thereof will be omitted.

The third substrate 120 may be formed on the first surface 110A of the second substrate 110. The third substrate 120 may be formed of at least one selected from an Si substrate, a Ge substrate, an SiGe substrate, and an SOI substrate. The third substrate 120 may include a semiconductor material, for example, a Group IV semiconductor, a Group III-V compound semiconductor, or a Group II-VI oxide semiconductor. The third substrate 120 may be a bulky wafer or an epitaxial layer. The third substrate 120 may be the same substrate as the second substrate 110, but exemplary embodiments are not limited thereto. The third substrate 120 may be many other types of substrates as well.

An inter-substrate connection member 410 may be interposed between the second substrate 110 and the third substrate 120. The second substrate 110 and the third substrate 120 may be electrically and/or physically connected to each other by the inter-substrate connection member 410. The inter-substrate connection member 410 may be formed of at least one selected from a solder ball, a pin grid array, a ball grid array, and a micro-pillar grid array (MPGA). According to an exemplary embodiment, the inter-substrate connection member 410 may be a solder ball. The inter-substrate connection member 410 may be attached to the first surface 110A of the second substrate 110 by using a thermal compression process and/or a reflow process.

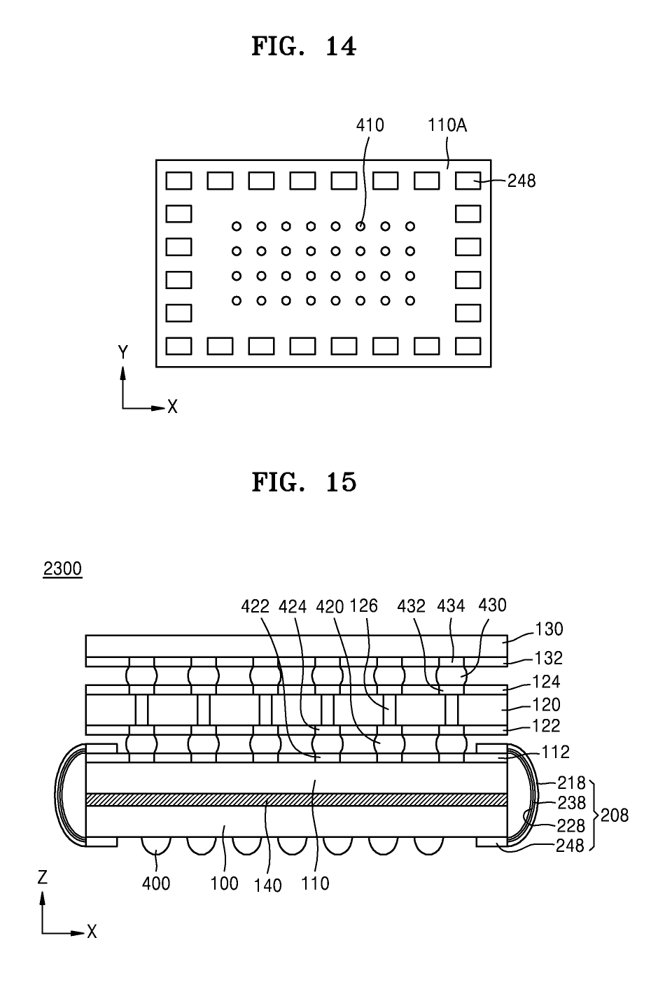

A plurality of conductive pads 248 may be formed on edges of the first surface 110A of the second substrate 110, respectively. Although FIG. 12 exemplarily illustrates that the plurality of conductive pads 248 are formed on only an edge of the first surface 110A and an opposite edge to the edge of the first surface 110A, exemplary embodiments are not limited thereto. In addition, although a portion of the inter-substrate connection member 410 is exposed in FIG. 12, exemplary embodiments are not limited thereto, and the entire portion of the inter-substrate connection member 410 may be surrounded by the plurality of conductive pads 248 (see FIG. 14).

In the semiconductor package 2200 according to an exemplary embodiment, the inter-substrate connection member 410 is formed on a portion of the first surface 110A of the second substrate 110 where the flexible interconnection member 206 is not formed, the third substrate 120 is stacked on the second substrate 110, and the third substrate 120 is connected to the inter-substrate connection member 410. Thus, more semiconductor devices may be mounted, and therefore, compact and high-performance semiconductor packages may be realized.

FIG. 14 is a plan view of an exemplary embodiment of the first surface 110A of the second substrate 110 of the semiconductor package 2200 of FIGS. 12 and 13.

Referring to FIG. 14, the first surface 110A of the second substrate 110 may be formed in a rectangular structure extending in the first direction (e.g., the X direction) and the third direction (e.g., the Z direction). The plurality of conductive pads 248 may be arranged in parallel to each other in the first direction (e.g., the X direction) and the third direction (e.g., the Z direction), on the four edges of the first surface 110A. Although FIG. 14 illustrates that the plurality of conductive pads 248 are formed on all of the four edges of the first surface 110A and arranged in parallel to each other in the first direction (e.g., the X direction) and the second direction (e.g., the Y direction), exemplary embodiments are not limited thereto, and various modifications may be made to the plurality of conductive pads 248 depending on the number of flexible interconnection members 208 with respect to the number of input/output (I/O) connection terminals connected to the first substrate 100 (see FIGS. 12 and 13). For example, the plurality of conductive pads 248 may be formed on one edge of the first surface 110A or may be formed on only two edges, namely, an edge of the first surface 110A and an opposite edge to the edge of the first surface 110A.

The inter-substrate connection member 410 may be formed on a portion of the first surface 110A of the second substrate 110 where the plurality of conductive pads 248 are not formed, namely, on a center portion of the first surface 110A. The inter-substrate connection member 410 may be surrounded by the plurality of conductive pads 248. Although FIG. 14 exemplarily illustrates that 8 inter-substrate connection members 410 are arranged in the first direction (e.g., the X direction) and 4 inter-substrate connection members 410 are arranged in the second direction (e.g., the Y direction), exemplary embodiments are not limited thereto, and the inter-substrate connection members 410 may be arranged differently according to the number of I/O terminals of the second substrate 110, the number of I/O terminals of the third substrate 120, and other considerations.

FIG. 15 is a cross-sectional view of a semiconductor package 2300 according to another exemplary embodiment.

Referring to FIG. 15, the semiconductor package 2300 includes the same components as those of the semiconductor package 2100 of FIG. 11 and may further include a third substrate 120, a fourth substrate 130 formed on the third substrate 120, first inter-substrate connection members 420 connecting the second substrate 110 to the third substrate 120, and second inter-substrate connection members 430 connecting the third substrate 120 to the fourth substrate 130. A description of the same components of the semiconductor package 2300 which are also part of the semiconductor package 2100 of FIG. 11 will be omitted.

The third substrate 120 may be formed on the first surface 110A of the second substrate 110, and the fourth substrate 130 may be formed on the third substrate 120. Thus, the second substrate 110, the third substrate 120, and the fourth substrate 130 may be sequentially stacked. The third substrate 120 and the fourth substrate 130 may each be formed of at least one selected from an Si substrate, a Ge substrate, an SiGe substrate, and an SOI substrate. The third substrate 120 and the fourth substrate 130 may each include a semiconductor material, for example, a Group IV semiconductor, a Group III-V compound semiconductor, or a Group II-VI oxide semiconductor. The third substrate 120 and the fourth substrate 130 may each be a bulky wafer or an epitaxial layer. The third substrate 120 and the fourth substrate 130 may be the same substrates, but exemplary embodiments are not limited thereto. The third substrate 120 and the fourth substrate 130 may be different types of substrates. The third substrate 120 and the fourth substrate 130 may have substantially equal planar areas.

An upper protection layer 112 may be formed to cover the first surface 110A of the second substrate 110. The upper protection layer 112 protects the second substrate 110 and may be formed of, for example, solder resist.

First upper pads 422 may be formed through the upper protection layer 112 and may be electrically and/or physically connected to first lower pads 424 via the first inter-substrate connection members 420. The first upper pads 422 may be formed of a conductive material. The first upper pads 422 may be formed of Al or Cu and may be formed by pulse plating or direct current plating. However, a material and a method used to form the first upper pads 422 are not limited thereto.

A first lower protection layer 122 may be formed on a lower surface of the third substrate 120, and a first upper protection layer 124 may be formed on an upper surface of the third substrate 120. The first lower protection layer 122 and the first upper protection layer 124 protect the third substrate 120 from the outside. The first lower protection layer 122 and the first upper protection layer 124 may be formed of an oxide layer, a nitride layer, or a double layer formed of an oxide layer and a nitride layer. The first lower protection layer 122 and the first upper protection layer 124 may be formed of an oxide layer or a nitride layer, for example, an Si oxide (SiO₂) layer or a Si nitride (SiNx) layer, by high-density plasma chemical vapor deposition (HD-CVD).

The first lower pads 424 may be formed of a conductive material on the lower surface of the third substrate 120 and may be electrically and/or physically connected to penetrating electrodes 126 via the third substrate 120. The first lower pads 424 may be formed of Al or Cu and may be formed by pulse plating or direct current plating. However, a material and a method used to form the first lower pads 424 are not limited thereto.

The inter-substrate connection members 420 may be formed on the first upper pads 422. The first inter-substrate connection members 420 may be formed of a conductive material, such as Cu, Al, Ag, Sn, Au, or solder. However, a material used to form the first inter-substrate connection members 420 is not limited thereto. The first inter-substrate connection members 420 may be formed as a single layer or as multiple layers. For example, when the first inter-substrate connection members 420 are formed as multiple layers, the first inter-substrate connection members 420 may include a Cu pillar and a solder. When the first inter-substrate connection members 420 are formed as single layers, the first inter-substrate connection members 420 may be formed of an Sn—Ag solder or Cu.

The penetrating electrodes 126 may penetrate through the third substrate 120 and may be connected to second upper pads 432. According to an exemplary embodiment, the penetrating electrodes 126 may be through silicon vias (TSVs). The penetrating electrodes 126 may each include a barrier metal layer and a wiring metal layer. The barrier metal layer may be formed of one selected from titanium (Ti), tantalum (Ta), titanium nitride (TiN), and tantalum nitride (TaN), or may be formed as a stack of at least two selected therefrom. The wiring metal layer may include, for example, at least one selected from the group consisting of aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), lutetium (Ru), tantalum (Ta), tellurium (Te), titanium (Ti), tungsten (W), zinc (Zn), and zirconium (Zr). For example, the wiring metal layer may be formed of one selected from tungsten (W), aluminum (Al), and copper (Cu), or may be formed as a stack of at least two selected therefrom. However, a structure and a material used to form the penetrating electrodes 126 are not limited thereto.

The third substrate 120 may be electrically and/or physically connected to the fourth substrate 130 stacked on the third substrate 120 via the penetrating electrodes 126. In detail, the penetrating electrodes 126 may be connected to the second upper pads 432 and may be electrically and/or physically connected to the second lower pads 434 via the second inter-substrate connection members 430. The second inter-substrate connection members 430 may be interposed between the third substrate 120 and the fourth substrate 130. Since structures and materials of the second upper pads 432 and the second lower pads 434 are the same as those of the first upper pads 422 and the first lower pads 424 and a structure and a material of the second inter-substrate connection members 430 are the same as those of the first inter-substrate connection members 420, a repeated description thereof will be omitted.

Since the semiconductor package 2300 according to an exemplary embodiment includes the penetrating electrodes 126 to electrically and/or physically connect the third substrate 120 to the fourth substrate 130, the entire size of a semiconductor package on which a plurality of semiconductor substrates are stacked may be reduced. Thus, more semiconductor substrates and more semiconductor devices may be stacked, resulting in realizing high-performance and compact semiconductor packages. Although the third substrate 120 and the fourth substrate 130 are stacked on the second substrate 110 in FIG. 15, exemplary embodiments are not limited thereto, and a plurality of semiconductor substrates may be stacked.

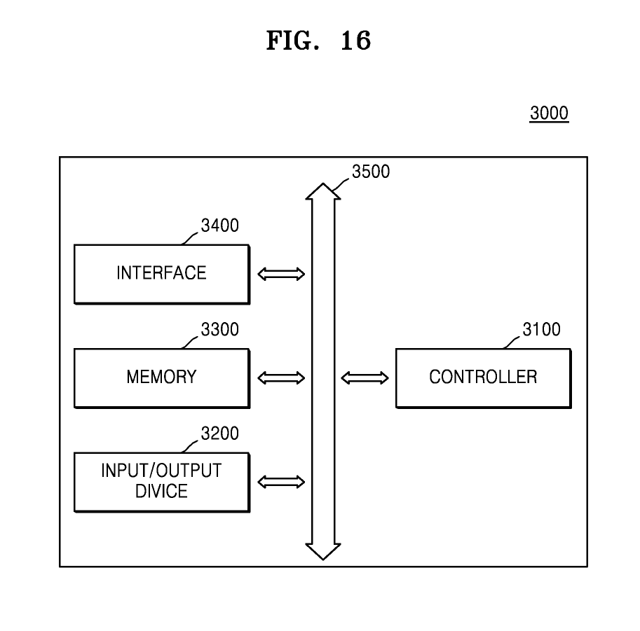

FIG. 16 is a block diagram of an electronic system 300 including a semiconductor package according to any of the exemplary embodiments.

Referring to FIG. 16, the electronic system 3000 may include a controller 3100, an I/O device 3200, a memory 3300, and an interface 3400. The electronic system 3000 may be a mobile system or a system that transmits or receives information. The mobile system may be a PDA, a portable computer, a web tablet, a wireless phone, a mobile phone, a digital music player, or a wearable device including a smart watch.

The controller 3100 may execute a program and control the electronic system 3000. The controller 3100 may be a microprocessor, a digital signal processor, a microcontroller, or a device similar to these devices. The I/O device 3200 may be used to input or output the data of the electronic system 3000.

The electronic system 3000 may be connected to an external device, for example, a personal computer or a network, by using the I/O device 3200, and thus may exchange data with the external device. The I/O device 3200 may be a keypad, a keyboard, or a display. The I/O device 3200 may include a flexible device, for example, a flexible display. The memory 3300 may store a code and/or data for operating the controller 3100, and/or store data processed by the controller 3100. The memory 3100 and the memory 3300 may include any of the semiconductor packages 1000 through 2300 according to an exemplary embodiment. The interface 3400 may provide a data transmission path between the electronic system 3000 and another external device. The controller 3100, the I/O device 3200, the memory 3300, and the interface 3400 may communicate with each other via a bus 3500.

For example, the electronic system 3000 may be used in a mobile phone, an MP3 player, a navigation, a portable multimedia player (PMP), a solid state disk (SSD), or a wearable device.

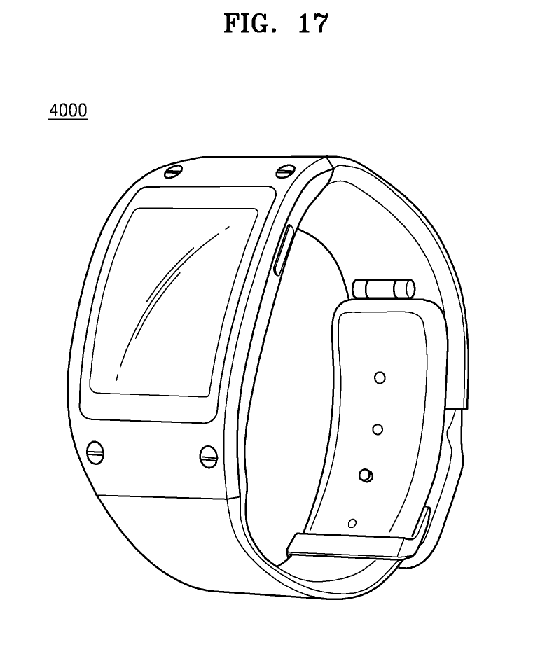

FIG. 17 is a perspective view of an electronic device to which a semiconductor package according to any of the exemplary embodiments may be applied.

FIG. 17 illustrates an example in which the electronic system 3000 of FIG. 16 is applied to a wearable device 4000. The wearable device 4000 is an electronic device configured to be wrapped around part of a human body such as a wrist. For example, the wearable device 4000 may be a smart watch or electronic eyeglasses that are connected to a mobile phone and provide a text message, an e-mail, and information of a schedule and the like. Since the wearable device 4000 is configured to be wrapped around part of a human body, for example, by being attached to a wrist, a flexible semiconductor package capable of being rolled, folded, stretched, or the like may be needed. Thus, the semiconductor packages 1000 through 2300 may be implemented in the wearable device 4000.

While the inventive concept has been particularly shown and described with reference to exemplary embodiments thereof, it will be understood that various changes in form and details may be made therein without departing from the spirit and scope of the following claims.

What is claimed is:

1. A semiconductor package comprising:
a first substrate;
a second substrate disposed on the first substrate to be spaced apart from the first substrate, and comprising an active region configured to receive and mount semiconductor devices; and
a flexible interconnection member electrically connecting the first substrate to the second substrate,
wherein the flexible interconnection member comprises a flexible film and a metal wiring member formed on the flexible film.

2. The semiconductor package of claim 1, wherein the flexible film is polyimide.

3. The semiconductor package of claim 1, wherein the flexible interconnection member further comprises a metallic adhesion member interposed between the metal wiring member and the flexible film.

4. The semiconductor package of claim 1, wherein
the flexible interconnection member further comprises a conductive pad formed on a surface of the first substrate and the active region of the second substrate, and
the conductive pad contacts a side of the flexible film and a side of the metal wiring member.

5. The semiconductor package of claim 1, further comprising a support member formed on an edge of an upper surface of the first substrate,
wherein the support member supports the upper surface of the first substrate and a lower surface of the second substrate such that the upper surface of the first substrate is spaced apart from the lower surface of the second substrate by a predetermined distance.

6. The semiconductor package of claim 1, wherein the metal wiring member extends in a first direction from the second substrate to the first substrate and a plurality of the metal wiring members are arranged parallel to each other in a second direction perpendicular to the first direction.

7. The semiconductor package of claim 1, wherein
a plurality of the flexible interconnection members are provided,
the plurality of flexible interconnection members each extend in a first direction from the second substrate to the first substrate and are arranged parallel to each other in a second direction perpendicular to the first direction, and
a width of the flexible film in the second direction is substantially equal to a width of the metal wiring member in the second direction.

8. The semiconductor package of claim 1, wherein
the first substrate comprises a printed circuit board comprising an active region,
the second substrate comprises a semiconductor substrate comprising an active region and an inactive region formed opposite to the active region, and
the flexible interconnection member electrically connects the active region of the first substrate to the active region of the second substrate.

9. The semiconductor package of claim 8, wherein a surface opposite to the active region of the first substrate faces the active region of the second substrate.

10. The semiconductor package of claim 8, wherein the active region of the first substrate faces the active region of the second substrate.

11. A semiconductor package comprising:
a first substrate having a lower surface on which an active region is formed;
a second substrate comprising a first surface on which an active region is formed and a second surface opposite to the first surface;
an adhesion layer interposed between an upper surface of the first substrate and the second surface of the second substrate; and
a flexible interconnection member that connects the lower surface of the first substrate to the first surface of the second substrate.

12. The semiconductor package of claim 11, wherein the flexible interconnection member comprises:
a flexible film;
a metal wiring member formed on an upper surface of the flexible film; and
a metallic adhesion member interposed between the flexible film and the metal wiring member.

13. The semiconductor package of claim 11, wherein a size of a planar area of the first substrate is substantially equal to a size of a planar area of the second substrate.

14. The semiconductor package of claim 11, further comprising a first conductive pad formed on edges of the lower surface of the first substrate and a second conductive pad formed on edges of the first surface of the second substrate,
wherein the first conductive pad is connected to a first end of the flexible interconnection member, and the second conductive pad is connected to a second end opposite to the first end of the flexible interconnection member.

15. The semiconductor package of claim 11, further comprising an external connection pad formed on the lower surface of the first substrate and connected to an external device,
wherein the external connection pad is surrounded by the flexible interconnection member.

16. A semiconductor package, comprising:
a first substrate;
a second substrate; and
a flexible interconnection member electrically connecting the first substrate to the second substrate,
wherein the flexible interconnection member comprises a metallic adhesion layer and a wiring member formed on the metallic adhesion layer.

17. The semiconductor package of claim 16, wherein the metallic adhesion layer comprises at least one selected from chromium (Cr), nickel (Ni), and a Cr—Ni alloy.

18. The semiconductor package of claim 16, wherein the flexible interconnection member further comprises a flexible film, and the metallic adhesion layer is formed on the flexible film.

19. The semiconductor package of claim 16, wherein the metallic adhesion layer is thinner than the flexible film.

20. The semiconductor package of claim 16, wherein the first substrate comprises a flexible printed circuit board (PCB).
